(19) United States
(12) Patent Application Publication
(10) Pub. No.: US 2026/0177589 A1
(43) Pub. Date: Jun. 25, 2026

(54) ELECTRICAL CURRENT SENSOR

(71) Applicant: PIHER SENSORS & CONTROLS, S.A., Tudela (ES)

(72) Inventors: David Perez Ciaurriz, Tudela (ES); koldo Ruiz Rodero, Tudela (ES); Bram Erik Vanneste, Tudela (ES); Peter Nuechter, Tudela (ES); Joe Milewski, Tudela (ES)

(21) Appl. No.: 19/129,250

(22) PCT Filed: Nov. 10, 2023
(86) PCT No.: PCT/ES2023/070670

§ 371 Date: May 12, 2025

(30) Foreign Application Priority Data
Nov. 11, 2022 (ES) P202230975

(51) Int. Cl. G01R 15/20; G01R 19/00

(52) U.S. Cl. CPC G01R 15/202; G01R 15/205; G01R 19/0092

(57) ABSTRACT

The invention relates to a current sensor formed by an integrated circuit (6), preferably of the TMR magnetic type, mounted on a PCB (5) and also comprising additional circuitry to protect the sensor from possible surges and electrical and electromagnetic noise, thus providing electromagnetic immunity. All these components are mounted in a casing (1) typically made of plastic, preferably with an opening for connecting the system. An electrically conductive bar or busbar (4) may be inserted through the casing to allow the circulation of the electrical current to be measured. The sensor provides an analogue output proportional to the current of an electrical conductor inserted through the casing.

### PURPOSE OF THE INVENTION

The present invention relates to an electrical current sensor whose purpose is to provide a more precise, faster, smaller, lighter sensor with lower energy consumption, better linearity, greater stability, high electromagnetic immunity, and reduced manufacturing cost.

### BACKGROUND OF THE INVENTION

Electric vehicles use a different automotive technology compared to that used by conventional vehicles. Electric and hybrid electric vehicles use numerous applications where electric current measurement is necessary, such as in DC-DC converters, systems like the Battery Management System (BMS), current inverters, or the vehicles'electric traction systems, among others, in addition to systems associated with electrification, such as the various types of wall chargers and on-board chargers.

The performance of electric vehicles depends on the vehicle's battery, with current sensors being responsible for detecting the current in batteries, identifying overloads, helping to reduce emission levels, and controlling the circulation of electrical energy within the vehicle. Therefore, with the ongoing drive towards vehicle electrification, technological advancements in this automotive component are critical and essential.

### DESCRIPTION OF THE INVENTION

It should be noted that current sensors need to be increasingly more accurate, faster, smaller and have lower energy consumption. This makes it necessary to use technologies that are different from those commonly used. In addition, it is necessary to take into account that the sensors are situated in environments with a lot of electromagnetic noise, with continuous high-power electrical switching and a large number of metallic elements, which generate large disturbances and can lead to malfunctioning or render the sensor inoperative. It is therefore imperative to design a sensor with high electromagnetic immunity.

The electrical current sensor proposed in the invention can solve the above-mentioned problems, based on a highly effective solution.

In some configurations, an electrical current sensor (AC or DC) is capable of measuring the circulation of current through an electric conductor, for example a busbar. The busbar may pass through the casing or be positioned next to the casing.

The sensor can be used to measure the current in high current and high voltage systems, battery management applications, DC/DC converters or inverters, providing a fully insulated contact free measurement system.

The sensor can be comprised of a magneto resistive type integrated circuit such as TMR, GMR or AMR, or a Hall effect type magnetic integrated circuit, mounted on a PCB, also comprising additional circuitry to protect the sensor from possible surges, and electrical and electromagnetic noise, thus providing electromagnetic immunity.

The components can be mounted in a plastic casing, designed to facilitate a connector through an opening or with an integrated connector for system wiring, a connector which is not necessary when the communication is wireless by radio frequency.

An electrically conductive bar or busbar may be inserted through the casing to allow the circulation of the electric current to be measured. The busbar or electric conductor may be attached to the casing or separate from it. In some cases, the casing is attachable to an electrically conductive bar.

The sensor may include an analogue output proportional to the current of an electric conductor inserted through the casing. At this point it should be added that it is possible to use digital outputs such as CAN, SENT or LIN, as well as the possibility of including additional functionalities such as temperature measurement and transmission of this data by analogue or digital communication.

Temperature measurement is a functionality that can be added to the sensor to check for possible overheating of the busbar and therefore a malfunction of the electrical system.

### BRIEF DESCRIPTION OF THE DRAWINGS

To complement the description given below and with the aim of providing a better understanding of the characteristics of the invention, in line with a preferred example of a practical embodiment thereof, a set of drawings is included as an integral part of said description, for illustrative and non-limiting purposes:

FIG. 1 shows a perspective view of an electrical current sensor made in accordance with the object of the present invention.

FIG. 2 shows a view of the assembly in FIG. 1 in reverse perspective.

FIG. 3 shows a view similar to that of FIG. 1, but with the casing of the device without its top cover.

FIG. 4 shows a longitudinal section view of the device.

FIG. 5 shows an exploded view of one way of applying the busbar or conductor whose current is to be measured by the sensor of the invention.

FIG. 6 shows a view similar to that of FIG. 5 but corresponding to a variant embodiment in which the means of sensorization are duplicated for the same busbar or conductor whose current is to be measured.

FIG. 7 shows a view similar to that of FIG. 1 but corresponding to a variant embodiment in which the sensor is capable of independently measuring the current circulating through several busbars or conductors.

FIG. 8 shows a longitudinal section view of the assembly in FIG. 7.

FIG. 9 finally shows a detailed perspective of a possible realization for the busbar used in the sensor of the invention.

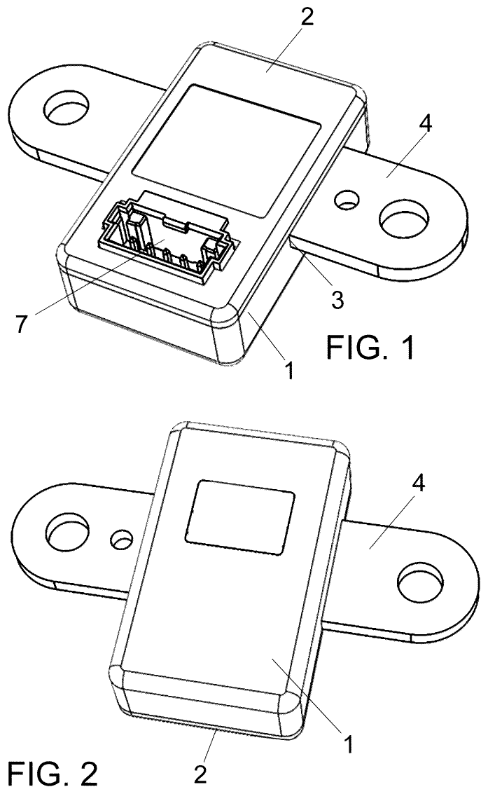

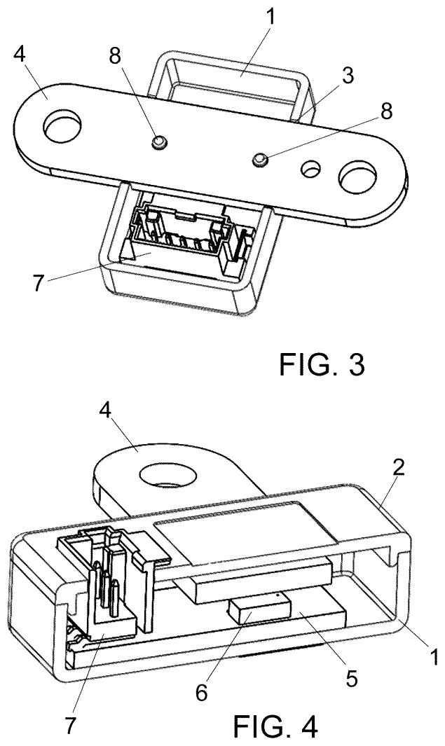

### PREFERRED EMBODIMENT OF THE INVENTION

In view of the aforementioned figure, it can be seen how the sensor of the invention is made up of a casing (1), preferably made of plastic, fitted with a closing cover (2), and at least one opening (3) between the two for the insertion of at least one electric conductor or busbar (4).

Inside the casing (1) there is a printed electronic circuit or PCB (5) on which at least one TMR (6) magneto resistive integrated circuit is mounted (one for each opening (3) for the insertion of the corresponding electric conductor or busbar (4)), strategically placed in a central position and keeping a fixed distance from the electric conductor or busbar (4) and through which the electric current to be measured circulates, thus achieving a non-intrusive, contact-free measurement system.

The sensor does not require a magnetic concentrate system, of an electromagnetic core type, although an electromagnetic concentrator may be used in some cases. The system comprising a magneto resistive type integrated circuit also known as Tunnel Magnetoresistance or TMR (6) and an electric conductor or busbar (4) guarantees the same arrangement and distance throughout the useful life of the sensor, using fastening devices for the PCB (5) and Busbar.

The PCB (5) includes additional circuitry to protect the sensor from surges, and electrical and electromagnetic noise.

The busbar (4) through which the electric current circulates will be made of materials with high electrical conductivity, generally copper or aluminum.

The busbar may be integrated in the sensor, connected at lugs (8), through holes (8′), depending on the application, forming part of the sensor or the sensor may have a fastening system, such as clamp-on, screw or similar that allows the sensor to be attached to a busbar external to the sensor.

A special design of the busbar is possible, based on an elongated laminar body in which strategically placed cuts (9) are made, arranged transversally and in a staggered pattern, so that the current circulates in a U-shape which will generate two magnetic fields of equal and opposite magnitude resulting in a measurement of the magnetic field free of external influences, measuring the algebraic difference between the values of these two magnitudes.

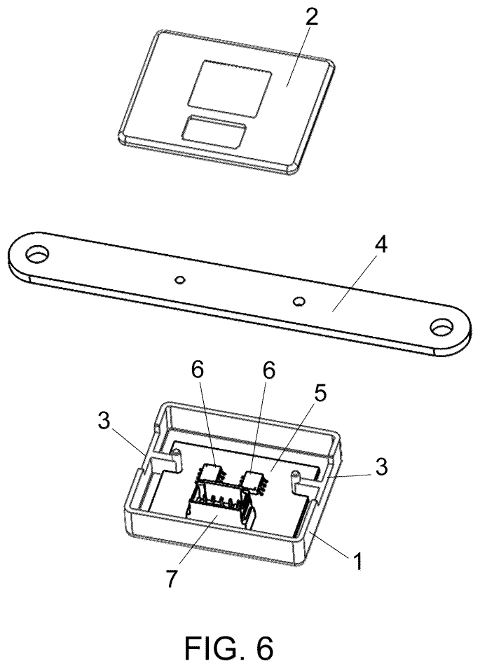

According to the variant embodiment of FIG. 6, it is possible to use two magnetic type integrated circuits mounted on the PCB positioned inside the same sensor.

These can be placed in the same direction allowing the calculation of the arithmetic average of the values obtained. They may also be placed in opposite direction, obtaining opposite magnitudes that allow the measurement of the difference in the magnetic field generated by the busbar (4) and the elimination of any noise or external magnetic field.

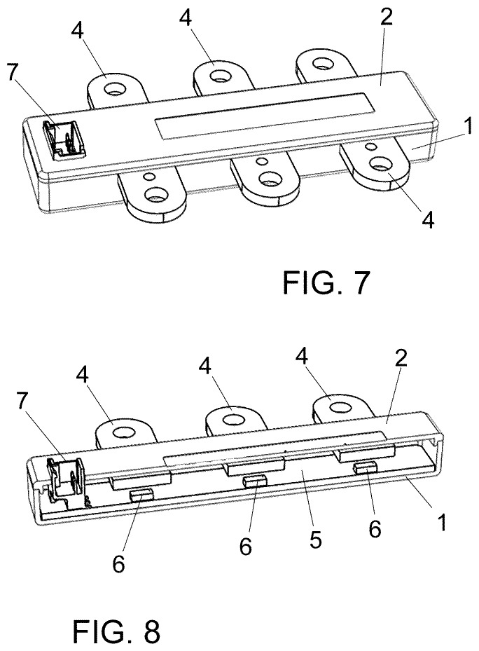

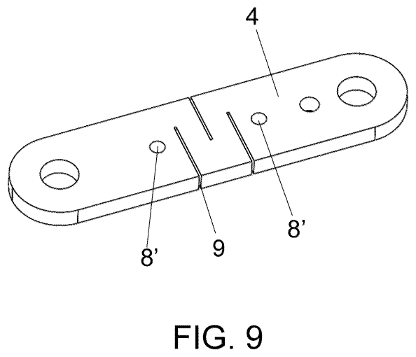

According to the variant embodiment of FIGS. 7 and 8, in applications where it is necessary to measure the current circulating through more than one busbar in parallel, generally the three phases used in electric vehicle propulsion systems, 3 integrated circuits of the TMR magnetic type (6), one for each busbar (4), integrated within the same device or sensor, will be used. In other cases, the sensor may include two busbars and their corresponding TMR integrated circuits (6), or more than three busbars and their corresponding number of TMR integrated circuits (6).

The PCB includes a connector (7) with which the value of the current circulating through the sensor is obtained, preferably by means of analogue signal condition proportional to the current.

Optionally, this measurement can be sent using other means and digital communication protocols such as CAN or LIN. It is even possible to use RF wireless technology to communicate the value of the current.

Returning again to the casing (1) cover (2) assembly, these elements will be attached by means of ultrasound or other means of fastening (such as mechanical fasteners or adhesives) having already inserted the busbar (4) between them, although it is possible to remove the cover from the casing and fill the device with an epoxy type or hot-melt resin that provides the system with protection from dust, humidity and external agents.

The device has a connector (7) with access through an opening or integrated in the casing itself for connecting the system. This connector may not be necessary in the event of RF Wireless technology.

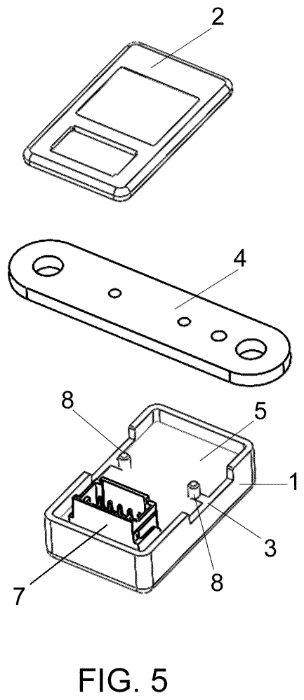

Referring to FIG. 5, the sensor does not include an integrated busbar, but the sensor is configured to be coupled near or directly to an external busbar. For example, a busbar located in an electric vehicle charging station. The sensor may include a casing configured to be coupled to the busbar or other fastening component or adapter in close proximity to the busbar. This adapter and the casing must ensure the direction with respect to the electric conductor or busbar. The shape of this adapter may correspond to the shape of the busbar, facilitating correct fastening.

The sensor obtained as a result is an improvement on the current ones in the market as it is more precise, has better linearity and is faster. The elimination of the magnetic concentrator makes it smaller, lighter and cheaper to manufacture.

What is claimed is:

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. An electrical current sensor comprising:
a) a casing (1), a cover (2), wherein said casing (1) and said cover (2) define at least one opening (3) configured to allow passage of at least one electric busbar (4) from one end of said casing (1) to the opposite side thereof, wherein an electrical current to be measured flows through said busbar (4);
b) a printed electronic circuit board (5) disposed within said casing (1), wherein at least one integrated circuit (6) for detecting electric current is mounted on said printed electronic circuit (5), said integrated circuit (6) is a tunnel magneto-resistance type, wherein said integrated circuit is positioned at a fixed distance from said busbar (4); and
c) a connector (7) mounted on said printed electronic board (5), wherein said connector (7) is configured to obtain an output value of said electrical current while flowing through said sensor.

18. The electrical current sensor of claim 17, wherein said integrated circuit (6) is based on other magnetic technologies, such as Hall effect.

19. The electrical current sensor of claim 17, wherein said busbar (4) is integrated in said sensor and includes a fastening and positioning system such as a pin, screw, or similar fixation mechanism between said casing (1) or said printed electronic circuit (5) and said busbar (4).

20. The electrical current sensor of claim 17, wherein said busbar (4) is independent from said sensor and is configured to be attached thereto using conventional fastening systems such as clips or screws.

21. An electrical current sensor comprising:
a) a casing (1), a cover (2), wherein said casing (1) and said cover (2) define at least one opening (3), wherein a busbar (4) is external to said sensor without passing through thereof, wherein said sensor is coupled to said busbar (4) by means of screws, wherein an electrical current to be measured flows through said sensor;
b) a printed electronic circuit board (5) disposed within said casing (1), wherein at least one integrated circuit (6) for detecting electric current is mounted on said printed electronic circuit (5), said integrated circuit (6) is a tunnel magneto-resistance type, wherein said integrated circuit is positioned at a fixed distance from said busbar (4); and
c) a connector (7) mounted on said printed electronic board (5), wherein said connector (7) is configured to obtain an output value of said electrical current while flowing through said sensor.

22. The electrical current sensor of claim 17, wherein said busbar (4) is made of high electrical conductivity material, such as copper or aluminum.

23. The electrical current sensor of claim 17, wherein said busbar (4) is formed as elongated laminar body having staggered transverse cuts (9).

24. The electrical current sensor of claim 17, wherein said printed circuit board (5) includes two integrated circuits (6) placed in a same orientation relative to said busbar (4).

25. The electrical current sensor of claim 17, wherein said printed circuit board (5) includes two-integrated circuits (6) placed in opposite orientations relative to said busbar (4).

26. The electrical current sensor of claim 17, wherein said printed circuit board (5) includes three integrated circuits (6), wherein each of said integrated circuits (6) is associated with one of three independent busbar (4) of a three-phase circuit.

27. The electrical current sensor of claim 17, wherein said value of said electrical current is formed by a connector (7) providing analog signals corresponding to said electrical current flowing though said sensor.

28. The electrical current sensor of claim 17, wherein said output value of said electrical current includes digital communication signals such as CAN or LIN for transmitting said output value of said electrical current flowing through said sensor.

29. The electrical current sensor of claim 17, wherein said value includes a radiofrequency communication module for transmitting said output value of said electrical current flowing by said sensor.

30. The electrical current sensor of claim 17, wherein said cover (2) is made of an epoxy type or hot-melt resin to fill the interior of said casing (1).

31. The electrical current sensor of claim 17, wherein said printed circuit board (5) includes additional circuitry for protecting said sensor against overvoltage, electrical noise, and electromagnetic interference.

32. The electrical current sensor of claim 17, wherein said printed circuit board (5) includes additional circuitry for temperature sensing.
